(19) United States
(12) Patent Application Publication
(10) Pub. No.: US 2026/0206527 A1
(43) Pub. Date: Jul. 16, 2026

(54) APPARATUS FOR REAL-TIME LINE WIDTH MEASUREMENT IN DRY ETCHING PROCESS

(71) Applicant: Kyung Hwan JEONG, Hwaseong-si, Gyeonggi-do (KR)

(72) Inventor: Kyung Hwan JEONG, Hwaseong-si, Gyeonggi-do (KR)

(21) Appl. No.: 19/138,681

(22) PCT Filed: Nov. 28, 2023
(86) PCT No.: PCT/KR2023/019295

§ 371 Date: Jun. 13, 2025

(30) Foreign Application Priority Data
Dec. 29, 2022 (KR) 10-2022-0188641

(51) Int. Cl. H10P 72/00; H01J 37/32

(52) U.S. Cl. CPC H10P 72/0604; H01J 37/32972; H01J 37/32981; H10P 72/0421; H01J 2237/24578; H01J 2237/24585; H01J 2237/3341

(57) ABSTRACT

The present invention relates to an apparatus for real-time line width measurement in a dry etching process, wherein an apparatus for real-time line width measurement in a dry etching process according to the present invention includes a reaction chamber in which a dry etching process is performed, a mass spectrometer configured to measure gaseous substances in the reaction chamber during the dry etching process, and a calculation unit configured to calculate a line width (CD) using the following equation based on data measured by the mass spectrometer. CD={a1×Σ[amount of film etching byproducts]}×{a2×Σ[amount of oxygen byproducts]}×{a3×Σ[amount of fluorine byproducts]}/{a4×Σ[amount of etching gases]}, where a1, a2, a3 and a4 are predetermined proportional constants.

### TECHNICAL FIELD

The present invention relates to an apparatus for real-time line width measurement in a dry etching process.

### BACKGROUND ART

Semiconductor/display products undergo a manufacturing process of forming a specific structure composed of various film materials on a substrate, and a lithography process that is a combination of a deposition process, a photolithography process, and a dry etching process is a very important core process in manufacturing the semiconductor/display products. The dry etching process is a process of etching a thin film deposited on a substrate to form a specific structure using an etching gas, and determines a structure of the semiconductor/display product, and since whether the quality according to the result of the dry etching process has a significant impact on the characteristics of the product as a structure of the semiconductor/display product becomes increasingly miniaturized, an etching profile and etched line width resulting from the dry etching process are measured and inspected by measuring a sample after the process.

An optical critical dimension (OCD) measurement method using optics is mainly used as a method of measuring a critical dimension (CD) and etching profile resulting from the dry etching process, and in the case of so-called high aspect ratio dry etching of which results cannot be measured using the OCD measurement method, a focused ion beam (FIB) sample preprocessing method of cutting a sample and performing processing so that a line width can be analyzed is used to expose an etched cross-section, and then the etched line width and the etching profile are measured using a transmission electron microscopy (TEM) or scanning electron microscopy (SEM) analysis method. However, as a semiconductor product continues to become finer and more precise, an aspect ratio of a structure resulting from the dry etching process exceeds 20, and therefore, in the OCD method of performing optical measurement, the accuracy of etched structure measurement is degraded because light does not reach to the bottom of the etched structure, and the number of processes in which the measurement of the etched substructure is impossible is continuously increasing. Alternatively, after an FIB process is performed for etched line width measurement, a TEM/SEM analysis method cannot be applied to the measurement of mass-produced semiconductor/display products because the sample is cut and the product becomes unusable, only selectively sampled samples can be intermittently measured after tens or hundreds of products are subjected to the process, and as a result, since the products are mass-produced in a state in which the line width and structure in the dry etching process is not substantially measured, semiconductor/display products have to be mass-produced with a great risk of potential process defects. Further, the selectively sampled samples should be discarded, and a time required for measurement, preprocessing, manpower required for analysis work, and costs required for analyzer and infrastructure construction are continuously increasing, which has a negative impact on a production cost and productivity of semiconductor/display products.

### DETAILED DESCRIPTION OF INVENTION

### Technical Problem

The present invention is directed to providing an apparatus for real-time line width measurement in a dry etching process that is capable of measuring a line width inside a reaction chamber in real time in order to overcome the limitations of a conventional non-destructive analysis method such as an optical critical dimension (OCD) analysis method and a conventional destructive analysis method such as a focused ion beam (FIB) and scanning electron microscopy (SEM)/transmission electron microscopy (TEM) analysis method in a dry etching process.

### TECHNICAL SOLUTION

An apparatus for real-time line width measurement in a dry etching process according to the present invention includes a reaction chamber in which a dry etching process is performed, a mass spectrometer configured to measure gaseous substances in the reaction chamber during the dry etching process, and a calculation unit configured to calculate a line width (CD) using the following equation based on data measured by the mass spectrometer.

CD={a1×Σ[amount of film etching byproducts]}×{a2×Σ[amount of oxygen byproducts]}×{a3×Σ[amount of fluorine byproducts]}/{a4×Σ[amount of etching gases]},
where a1, a2, a3 and a4 are predetermined proportional constants.

Further, the film etching byproduct may include one or more of SiF, SiF2, SiF3, SiF4, SiCl, SiCl2, SiCl3, SiCl4, SiH, SiH2, SiH3, SiH4, CF, CF2, CF3, CF4, NF, NF2, NF3, OF, OF2, GeF, GeF2, GeF3, GeF4, BF, BF2, BF3, PF, PF2, PF3, WF, WF2, WF3, WF4, WF5, WF6, WCl, WCl2, WCl3, WCl4, WCl5, WCl6, AlCl, AlCl2, AlCl3, HfF, HfF2, HfF3, HfF4, HfF5, HfF6, CoF, CoF2, CoF3, and CoF4.

Further, the oxygen byproduct may include one or more of O2, O, CO, CO2, NO, NO2, SO, SO2, and H2O.

Further, the fluorine byproduct may include one or more of F, F2, and HF.

Further, the etching gas residue may include one or more of CF4, CHF3, CH2F2, CH3F, C2F2, C2F4, C2F6, C3F4, C3F6, C3F8, C4F6, C4F8, C4F10, HF, F2, HCl, Cl2, CCl4, HBr, Br2, HI, and I2.

Further, in the equation, “Σ[amount of film etching byproducts]” may be a sum of amounts of all film etching byproducts measured by the mass spectrometer, “Σ[amount of oxygen byproducts]” may be a sum of amounts of all oxygen etching byproducts measured by the mass spectrometer, “Σ[amount of fluorine byproducts]” may be a sum of amounts of all film etching byproducts measured by the mass spectrometer, or “Σ[amount of etching gases]” may be a sum of amounts of all etching gases measured by the mass spectrometer.

In the equation, “Σ[amount of film etching byproducts]” may be a sum of amounts of some substances among the film etching byproducts measured by the mass spectrometer, “Σ[amount of oxygen byproducts]” may be a sum of amounts of some substances among the oxygen etching byproducts measured by the mass spectrometer, “Σ[amount of fluorine byproducts]” may be a sum of amounts of some substances among the film etching byproducts measured by the mass spectrometer, or “Σ[amount of etching gases]” may be a sum of amounts of some substances among the etching gas measured by the mass spectrometer.

Some substances may include the top n substances found to have a high correlation through testing, where n is a predetermined natural number.

Further, some substances may be determined through deep learning or machine learning analysis.

Further, a1, a2, a3, and a4 may be equal to each other.

Further, at least some of a1, a2, a3, and a4 may be different from each other.

Further, a1, a2, a3, and a4 may be determined through deep learning or machine learning analysis.

Further, the calculation unit may calculate a top line width, a middle line width, and a bottom line width by calculating the line width for each time when the dry etching process is performed.

Furthermore, the present invention may provide a method for real-time line width measurement in a dry etching process.

In this case, the method for real-time line width measurement in a dry etching process according to the present invention includes measuring gaseous substances in the reaction chamber during the dry etching process using a mass spectrometer, and calculating a line width (CD) using the following equation based on data measured by the mass spectrometer.

$$CD = \{ a 1 \times \sum [ amount of film etching byproducts ] \} \times \{ a 2 \times \sum [ amount of oxygen byproducts ] \} \times \{ a 3 \times \sum [ amount of fluorine byproducts ] \} / \{ a 4 \times \sum [ amount of etching gases ] \} ,$$

where a1, a2, a3, and a4 are predetermined proportional constants.

Further, the film etching byproduct may include one or more of SiF, SiF2, SiF3, SiF4, SiCl, SiCl2, SiCl3, SiCl4, SiH, SiH2, SiH3, SiH4, CF, CF2, CF3, CF4, NF, NF2, NF3, OF, OF2, GeF, GeF2, GeF3, GeF4, BF, BF2, BF3, PF, PF2, PF3, WF, WF2, WF3, WF4, WF5, WF6, WCl, WCl2, WCl3, WCl4, WCl5, WCl6, AlCl, AlCl2, AlCl3, HfF, HfF2, HfF3, HfF4, HfF5, HfF6, CoF, CoF2, CoF3, and CoF4.

Further, the oxygen byproduct may include one or more of O2, O, CO, CO2, NO, NO2, SO, SO2, and H2O.

Further, the fluorine byproduct may include one or more of F, F2, and HF.

Further, the etching gas residue may include one or more of CF4, CHF3, CH2F2, CH3F, C2F2, C2F4, C2F6, C3F4, C3F6, C3F8, C4F6, C4F8, C4F10, HF, F2, HCl, Cl2, CCl4, HBr, Br2, HI, and I2.

Further, in the equation, “Σ[amount of film etching byproducts]” may be a sum of amounts of all film etching byproducts measured by the mass spectrometer, “Σ[amount of oxygen byproducts]” may be a sum of amounts of all oxygen etching byproducts measured by the mass spectrometer, “Σ[amount of fluorine byproducts]” may be a sum of amounts of all film etching byproducts measured by the mass spectrometer, or “Σ[amount of etching gases]” may be a sum of amounts of all etching gases measured by the mass spectrometer.

Further, in the equation, “Σ[amount of film etching byproducts]” may be a sum of amounts of some substances among the film etching byproducts measured by the mass spectrometer, “Σ[amount of oxygen byproducts]” may be a sum of amounts of some substances among the oxygen etching byproducts measured by the mass spectrometer, “Σ[amount of fluorine byproducts]” may be a sum of amounts of some substances among the film etching byproducts measured by the mass spectrometer, or “Σ[amount of etching gases]” may be a sum of amounts of some substances among the etching gas measured by the mass spectrometer.

Further, some substances include the top n substances found to have a high correlation through testing, where n is a predetermined natural number.

Further, some substances may be determined through deep learning or machine learning analysis.

Further, a1, a2, a3, and a4 may be equal to each other.

Further, at least some of a1, a2, a3, and a4 may be different from each other.

Further, a1, a2, a3 and a4 may be determined through deep learning or machine learning analysis.

Meanwhile, the present invention may provide a method of calculating a top line width, a middle line width, and a bottom line width by applying the method for real-time line width measurement in a dry etching process as described above for each time when the dry etching process is performed.

### Advantageous Effects

With the apparatus for real-time line width measurement in a dry etching process according to the present invention, it is possible to measure the line width inside the reaction chamber in real time by measuring gaseous substances in the reaction chamber during the dry etching process using a mass spectrometer and calculating the line width based on data measured by the mass spectrometer.

This makes it possible to early address a wafer that is not etched to have a desired line width during the process, thereby avoiding unnecessary post-processing, reducing manufacturing costs, and improving economic efficiency. Further, it is possible to perform an automatic process control function of continuously maintaining a high quality of the process through automatic control for a progress time or etching conditions of a real-time etching process. Further, since it is possible to monitor an etched line width for all wafers or samples without additional productivity reduction using a line width measurement method of performing measurement and calculation during the process without a separate etched line width measurement step, it is possible to avoid a potential risk of defects due to the limitation of a line width measurement scheme for performing measurement by intermittently sampling samples among all mass-produced samples in an existing line width measurement scheme, which allows the apparatus to be utilized for etching defect monitoring and yield improvement for all the mass-produced samples. Further, it is possible to diagnose a status of a semiconductor manufacturing facility by early detecting abnormalities in an etching environment such as the reaction chamber in real time, and thus to reduce a product defect rate and improve the productivity of good products.

### DESCRIPTION OF DRAWINGS

FIG. 1 is a schematic diagram of an apparatus for real-time line width measurement in a dry etching process according to an embodiment of the present invention.

FIG. 2 is a graph showing that a line width and an amount of SiF4 as an example of film etching byproducts are in a proportional relationship, with a horizontal axis representing the line width (nm) and a vertical axis representing an amount (a.u) of SiF4.

FIG. 3 is a graph showing that the line width and an amount of NO as an example of oxygen byproducts are in a proportional relationship, with a horizontal axis representing the line width (nm) and a vertical axis representing an amount (a.u.) of NO.

FIG. 4 is a graph showing that the line width and an amount of C4F6 as an example of an etching gas are in an inverse proportional relationship, with a horizontal axis representing the line width (nm) and a vertical axis representing an amount (a.u.) of C4F6.

FIG. 5 is a graph showing that the line width and {Σ[amount of film etching byproducts]×Σ[amount of oxygen byproducts]Σ[amount of fluorine byproducts]/Σ[amount of etching gases]} are in a proportional relationship, with a horizontal axis representing the line width (nm) and a vertical axis representing {Σ[amount of film etching byproducts]×Σ[amount of oxygen byproducts]×Σ[amount of fluorine byproducts]/Σ[amount of etching gases]}(a.u.).

### MODES OF THE INVENTION

An apparatus for real-time line width measurement in a dry etching process according to an embodiment of the present invention will be described in detail with reference to the drawings.

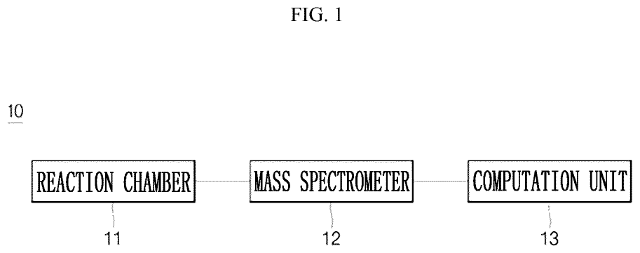

FIG. 1 is a schematic diagram of an apparatus 10 for real-time line width measurement in a dry etching process according to an embodiment of the present invention.

Referring to FIG. 1, the apparatus 10 for real-time line width measurement in a dry etching process includes a reaction chamber 11, a mass spectrometer 12, and a calculation unit 13.

A dry etching process is performed in the reaction chamber 11. For example, when an etching gas is injected and generates plasma in the reaction chamber 11, the etching gas chemically reacts on a surface of a wafer to generate volatile reaction byproducts, and the dry etching process may be performed so that the byproducts are attached to and detached from the surface of the wafer to remove the film material. Since the dry etching process and a configuration of the reaction chamber are substantially the same as those known in the art or can be easily derived therefrom by those skilled in the art, detailed description thereof will be omitted.

The mass spectrometer 12 serves to measure gaseous substances inside the reaction chamber 11 in real time during the dry etching process. The mass spectrometer 12 may be connected to be directly communicated to the inside of the reaction chamber 11 or may be connected to an exhaust line (a fore-line) of the reaction chamber 11. Since a configuration of the mass spectrometer itself is substantially the same as that known in the art or can be easily derived therefrom by those skilled in the art, detailed description thereof will be omitted.

The calculation unit 13 serves to calculate a line width based on data measured by the mass spectrometer 12.

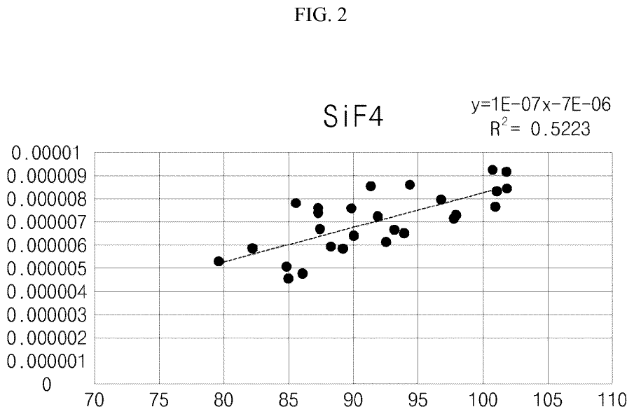

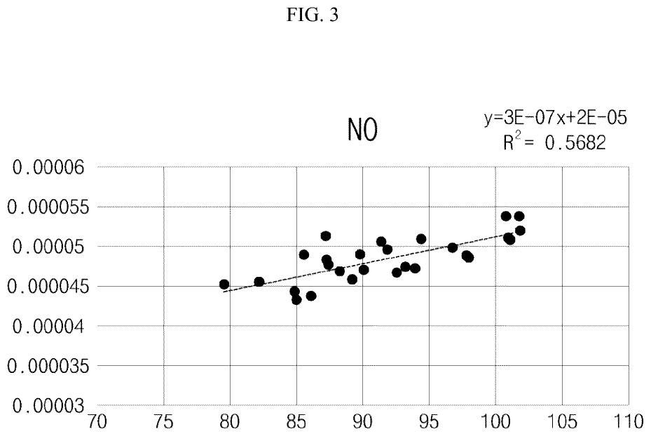

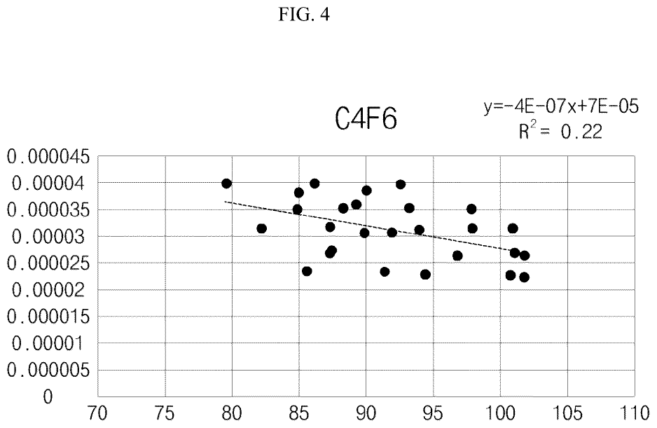

More specifically, the calculation unit 13 may calculate the line width (CD) using the following Equation 1, based on the fact that the line width is proportional to amounts of film etching byproducts, oxygen byproducts, and fluorine byproducts inside the reaction chamber 11 during the dry etching process and is inversely proportional to an amount of etching gases (see FIGS. 2 to 4).

$$CD = a \times \sum [ amount of film etching byproducts ] \times \sum [ amount of oxygen byproducts ] \times \sum [ amount of fluorine byproducts ] / \sum [ amount of etching gases ] , \qquad ( Equation 1 )$$

where, a is a proportional constant.

A value of a may be determined through testing. For example, a dry etching process for testing may be performed, gaseous substances in the reaction chamber 11 may be measured using the mass spectrometer 12, an actual line width may be measured, and a proportional constant may be obtained so that a result of substituting the data measured by the mass spectrometer 12 into Equation 1 has the same value as the actual line width. Furthermore, this testing may be repeatedly performed several times to obtain an optimal proportional constant, for example, by taking an average.

Further, the value of a may be determined through deep learning or machine learning analysis. Therefore, the accuracy can be further improved as the dry etching process is performed.

The film etch byproducts may include, for example, one or more of SiF, SiF2, SiF3, SiF4, SiCl, SiCl2, SiCl3, SiCl4, SiH, SiH2, SiH3, SiH4, CF, CF2, CF3, CF4, NF, NF2, NF3, OF, OF2, GeF, GeF2, GeF3, GeF4, BF, BF2, BF3, PF, PF2, PF3, WF, WF2, WF3, WF4, WF5, WF6, WCl, WCl2, WCl3, WCl4, WCl5, WCl6, AlCl, AlCl2, AlCl3, HfF, HfF2, HfF3, HfF4, HfF5, HfF6, CoF, CoF2, CoF3, and CoF4.

Further, the oxygen byproducts may include, for example, one or more of O2, O, CO, CO2, NO, NO2, SO, SO2, and H2O.

Further, the fluorine byproduct may include, for example, one or more of F, F2, and HF.

Further, the etching gas may include, for example, one or more of CF4, CHF3, CH2F2, CH3F, C2F2, C2F4, C2F6, C3F4, C3F6, C3F8, C4F6, C4F8, C4F10, HF, F2, HCl, C12, CCl4, HBr, Br2, HI, and I2.

However, the above materials are examples in which film materials, etching gases, and the like that are used in a typical semiconductor/display wafer dry etching process are taken into account, and the technical spirit of the present invention is not necessarily limited thereto and may vary depending on film materials, etching gases, and the like that are used in individual dry etching processes.

In an embodiment, the calculation unit 13 may calculate the line width using all data measured by the mass spectrometer 12. That is, Equation 1 may be specified as Equation 2 below.

$$CD = a \times \sum [ amount of all film etching byproducts ] \times \sum [ amount of all oxygen byproducts ] \times \sum [ amount of all fluorine byproducts ] / \sum [ amount of all etching gases ] \qquad ( Equation 2 )$$

For example, when SiF, SiF2, SiF3, and SiF4 are detected as the film etching byproducts by the mass spectrometer 12, “Σ[amount of all film etching byproducts]” in Equation 2 is a sum of the amounts of all the film etching byproducts (that is, a sum of the amounts of SiF, SiF2, SiF3, and SiF4. The same applies to the other oxygen byproducts, fluorine byproducts, and etching gases. In other words, in Equation 2, “Σ[amount of all oxygen byproducts]” is a sum of amounts of all oxygen byproducts measured by the mass spectrometer 12, “Σ[amount of all fluorine byproducts]” is a sum of amounts of all fluorine byproducts measured by the mass spectrometer 12, and “Σ[amount of all etching gases]” is a sum of amounts of all etching gases measured by the mass spectrometer 12.

In another embodiment, the calculation unit 13 may calculate the line width using some of the data measured by the mass spectrometer 12. That is, Equation 1 may be specified as Equation 3 below.

$$CD = a \times \sum [ amount of some etching byproducts ] \times \sum [ amount of some oxygen byproducts ] \times \sum [ amount of fluorine byproducts ] / \sum [ amount of etching gases ]$$

For example, when SiF, SiF2, SiF3, and SiF4 are detected as the film etching byproducts by the mass spectrometer 12, “Σ[amount of some film etching byproducts]” in Equation 3 is a sum of amounts of some substances (for example, only a sum of amounts of SiF2, SiF3, and SiF4 other than SiF) among SiF, SiF2, SiF3, and SiF4. The same applies to the other oxygen byproducts, fluorine byproducts, and etching gases. In other words, in Equation 3, “Σ[amount of some oxygen byproducts]” is a sum of amounts of some substances among the oxygen byproducts measured by the mass spectrometer 12, “Σ[amount of some fluorine byproducts]” is a sum of amounts of some substances among the fluorine byproducts measured by the mass spectrometer 12, and “Σ[amount of some etching gases]” is a sum of amounts of some substances among the etching gases measured by the mass spectrometer 12.

Which substance's data among the data measured by the mass spectrometer 12 will be used may be determined through testing.

For better understanding, for example, as described above, the film etching byproducts may include one or more of SiF, SiF2, SiF3, SiF4, SiCl, SiCl2, SiCl3, SiCl4, SiH, SiH2, SiH3, SiH4, CF, CF2, CF3, CF4, NF, NF2, NF3, OF, OF2, GeF, GeF2, GeF3, GeF4, BF, BF2, BF3, PF, PF2, PF3, WF, WF2, WF3, WF4, WF5, WF6, WCl, WCl2, WCl3, WCl4, WCl5, WCl6, AlCl, AlCl2, AlCl3, HfF, HfF2, HfF3, HfF4, HfF5, HfF6, CoF, CoF2, CoF3 and CoF4, which are used to calculate the line width depending on the film materials, etching gases, and the like used in the dry etching process, and the line width is compared with the actual line width. For example, as “Σ[amount of film etching byproducts]” in Equation 1, \textcircled{1} a result of calculating the line width by substituting only the amount of SiF, \textcircled{2} a result of calculating the line width by substituting only the amount of SiF2, \textcircled{3} a result of calculating the line width by substituting only the amount of SiF3, and \textcircled{4} a result of calculating the line width by substituting only the amount of SiF4 are recorded, which are listed in ascending order of their difference from the actual line width. The smaller this difference is, the higher the correlation of the substance. Therefore, the line width may be calculated using only the top n substances found to have a high correlation among the data measured by the mass spectrometer 12. Here, n is a natural number, and how many of top substances to use may be determined according to the need. The same applies to the other oxygen byproducts, fluorine byproducts, and etching gases.

Further, which substance's data among the data measured by the mass spectrometer 12 will be used may be determined through deep learning or machine learning analysis.

In another embodiment, all data measured by the mass spectrometer 12 may be used for some of the film etch byproducts, the oxygen byproducts, the fluorine byproducts, and the etching gases, and some of the data measured by the mass spectrometer 12 may be used for others. In this case, 16 combinations are possible. For better understanding, in one example, Equation 1 may be specified as Equation 4 below.

$$CD = a \times \sum [ amount of all film etch byproducts ] \times \sum [ amount of some oxygen byproducts ] \times \sum [ amount of all fluorine byproducts ] / \sum [ amount of some etching gases ] \qquad ( Equation 4 )$$

Furthermore, different proportional constants may be applied to the amount of film etch byproducts, the amount of oxygen byproducts, the amount of fluorine byproducts, and/or the amount of etching gases. That is, the line width may be calculated using Equation 5 below.

$$CD = \{ a 1 \times \sum [ amount of film etching byproducts ] \} \times \{ a 2 \times \sum [ amount of oxygen byproducts ] \} \times \{ a 3 \times \sum [ amount of fluorine byproducts ] \} / \{ a 4 \times \sum [ amount of etching gases ] \} , \qquad ( Equation 5 )$$

where, at least some of a1, a2, a3, and a4 may be equal to or different from each other. These proportional constants may be determined through testing or may be determined through deep learning or machine learning analysis.

Further, in Equation 5, all data measured by the mass spectrometer 12 may be used as in Equation 2, or some of the pieces of data measured by the mass spectrometer 12 may be used as in Equation 3. The former case is as in Equation 6 below, and the latter case is as in Equation 7 below.

$$CD = \{ a 1 \times \sum [ amount of all film etching byproducts ] \} \times \{ a 2 \times \sum [ amount of all oxygen byproducts ] \} \times \{ a 3 \times \sum [ amount of all fluorine byproducts ] \} / \{ a 4 \times \sum [ amount of all etching gases ] \} \qquad ( Equation 6 )$$

$$CD = \{ a 1 \times \sum [ amount of some film etching byproducts ] \} \times \{ a 2 \times \sum [ amount of some oxygen byproducts ] \} \times \{ a 3 \times \sum [ amount of some fluorine byproducts ] \} / \{ a 4 \times \sum [ amount of some etching gases ] \} \qquad ( Equation 7 )$$

Regarding Equation 7, which substance's data among the data measured by the mass spectrometer 12 will be used may be determined through testing or may be determined through deep learning or machine learning.

Of course, as in Equation 4, all data measured by the mass spectrometer 12 may be used for some of the film etch byproducts, the oxygen byproducts, the fluorine byproducts, and the etching gases, and some of the data measured by the mass spectrometer 12 may be used for others.

A method for real-time line width measurement in a dry etching process may be applied for each time when the dry etching process is performed, thereby calculating a top line width (top CD), a middle line width (middle CD), and a bottom line width (bottom CD). For example, the method for real-time line width measurement in a dry etching process according to the embodiment of the present invention may be applied to an early stage of the process to calculate the top line width, to a middle stage of the process to calculate the middle line width, and to a later stage of the process to calculate the bottom line width.

When the top line width is calculated, when the middle line width is calculated, and when the bottom line width is calculated, different proportional constants may be applied, and when some of the data measured by the mass spectrometer 12 is used as in Equations 3, 4, and 7, data related to different substances may be used.

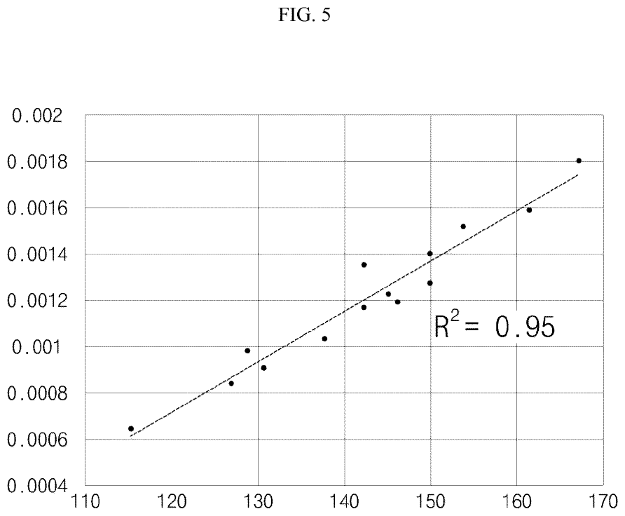

FIG. 5 is a graph showing that the line width and {Σ[amount of film etching byproducts]×Σ[amount of oxygen byproducts]×Σ[amount of fluorine byproducts]/Σ[amount of etching gases]} are in a proportional relationship, with a horizontal axis representing the line width (nm) and a vertical axis representing {Σ[amount of film etching byproducts]×Σ[amount of oxygen byproducts]×Σ[amount of fluorine byproducts]/Σ[amount of etching gases]}(a.u.).

Referring to FIG. 5, it can be seen that a correlation between the actual line width and {Σ[amount of film etching byproducts]×Σ[amount of oxygen byproducts]×Σ[amount of fluorine byproducts]/Σ[amount of etching gases]} used in the method for real-time line width measurement in a dry etching process according to the embodiment of the present invention is very high since a coefficient of determination R² is about 0.95. Therefore, it could be confirmed that the line width can be calculated with high accuracy using the method for real-time line width measurement in a dry etching process according to the embodiment of the present invention.

The apparatus 10 for real-time line width measurement in a dry etching process described above is only one of the apparatuses for real-time line width measurement in a dry etching process according to various embodiments of the present invention. The technical spirit of the present invention is not limited to the above embodiments and includes a range in which the present invention can be easily changed by those skilled in the art to which the present invention belongs, as described in the claims.

1. An apparatus for real-time line width measurement in a dry etching process, comprising:
a reaction chamber in which the dry etching process is performed;
a mass spectrometer configured to measure gaseous substances in the reaction chamber during the dry etching process; and
a calculation unit configured to calculate a line width (CD) using the following equation based on data measured by the mass spectrometer:
$$CD = \{ a 1 \times \sum [ amount of film etching byproducts ] \} \times \{ a 2 \times \sum [ amount of oxygen byproducts ] \} \times \{ a 3 \times \sum [ amount of fluorine byproducts ] \} / \{ a 4 \times \sum [ amount of etching gases ] \} ,$$
where a1, a2, a3 and a4 are predetermined proportional constants.

2. The apparatus for real-time line width measurement in a dry etching process of claim 1, wherein the film etching byproducts include one or more of SiF, SiF2, SiF3, SiF4, SiCl, SiCl2, SiCl3, SiCl4, SiH, SiH2, SiH3, SiH4, CF, CF2, CF3, CF4, NF, NF2, NF3, OF, OF2, GeF, GeF2, GeF3, GeF4, BF, BF2, BF3, PF, PF2, PF3, WF, WF2, WF3, WF4, WF5, WF6, WCl, WCl2, WCl3, WCl4, WCl5, WCl6, AlCl, AlCl2, AlCl3, HfF, HfF2, HfF3, HfF4, HfF5, HfF6, CoF, CoF2, CoF3, and CoF4.

3. The apparatus for real-time line width measurement in a dry etching process of claim 1, wherein the oxygen byproducts include one or more of O2, O, CO, CO2, NO, NO2, SO, SO2, and H2O.

4. The apparatus for real-time line width measurement in a dry etching process of claim 1, wherein the fluorine byproducts include one or more of F, F2, and HF.

5. The apparatus for real-time line width measurement in a dry etching process of claim 1, wherein the etching gas residue includes one or more of CF4, CHF3, CH2F2, CH3F, C2F2, C2F4, C2F6, C3F4, C3F6, C3F8, C4F6, C4F8, C4F10, HF, F2, HCl, Cl2, CCl4, HBr, Br2, HI and I2.

6. The apparatus for real-time line width measurement in a dry etching process of claim 1, wherein, in the equation,
“Σ[amount of film etching byproducts]” is a sum of amounts of all film etching byproducts measured by the mass spectrometer,
“Σ[amount of oxygen byproducts]” is a sum of amounts of all oxygen etching byproducts measured by the mass spectrometer,
“Σ[amount of fluorine byproducts]” is a sum of amounts of all film etching byproducts measured by the mass spectrometer, or
“Σ[amount of etching gases]” is a sum of amounts of all etching gases measured by the mass spectrometer.

7. The apparatus for real-time line width measurement in a dry etching process of claim 1, wherein, in the equation,
“Σ[amount of film etching byproducts]” is a sum of amounts of some substances among the film etching byproducts measured by the mass spectrometer,
“Σ[amount of oxygen byproducts]” is a sum of amounts of some substances among the oxygen etching byproducts measured by the mass spectrometer,
“Σ[amount of fluorine byproducts]” is a sum of amounts of some substances among the film etching byproducts measured by the mass spectrometer, or
“Σ[amount of etching gases]” is a sum of amounts of some substances among the etching gas measured by the mass spectrometer.

8. The apparatus for real-time line width measurement in a dry etching process of claim 7, wherein some substances include top n substances found to have a high correlation through testing, and n is a predetermined natural number.

9. The apparatus for real-time line width measurement in a dry etching process of claim 7, wherein some substances are determined through deep learning or machine learning analysis.

10. The apparatus for real-time line width measurement in a dry etching process of claim 1, wherein a1, a2, a3, and a4 are equal to each other.

11. The apparatus for real-time line width measurement in a dry etching process of claim 1, wherein at least some of a1, a2, a3, and a4 are different from each other.

12. The apparatus for real-time line width measurement in a dry etching process of claim 1, wherein a1, a2, a3, and a4 are determined through deep learning or machine learning analysis.

13. The apparatus for real-time line width measurement in a dry etching process of claim 1, wherein the calculation unit calculates a top line width, a middle line width, and a bottom line width by calculating the line width for each time when the dry etching process is performed.
